(19) United States
(12) Patent Application Publication
(10) Pub. No.: US 2017/0288660 A1
(43) Pub. Date: Oct. 5, 2017

(54) Ultra-Low Quiescent Current Multi-Function Switching Circuit and Method for Connecting a Voltage Source to an Output Load with Deep Sleep Capability

(71) Applicant: GLF INTEGRATED POWER INC., a Delaware corporation, Fremont, CA (US)

(72) Inventors: Stephen W. Bryson, Cupertino, CA (US); Ni Sun, Sunnyvale, CA (US)

(73) Assignee: GLF INTEGRATED POWER INC., a Delaware corporation, Fremont, CA (US)

(21) Appl. No.: 15/632,243

(22) Filed: Jun. 23, 2017

Related U.S. Application Data
(63) Continuation-in-part of application No. 14/586,586, filed on Dec. 30, 2014.
Application No. 14/586,586 is a continuation-in-part of application No. 14/638,989, filed on Mar. 4, 2015.
Application No. 14/638,989 is a continuation-in-part of application No. 14/469,270, filed on Aug. 26, 2014, now Pat. No. 9,647,657.

(51) Int. Cl. H03K 17/16

(52) U.S. Cl. CPC H03K 17/161

(57) ABSTRACT

Described are apparatus and methods for a load switch with reset and deep sleep capability. The slew rate control methods of the PMOS load switches contained in the load switch configuration is also described. A preferred slew rate control circuit includes a power PMOS transistor that is capable of handling load currents of several amperes along with an integrated controller. The integrated reset and deep sleep functions allow the user to control the basic timing control of the voltages that are required by the system and to save battery power in an extended deep sleep mode such as storage and shipping.

### RELATED APPLICATIONS

This application is a continuation-in-part (CIP) application of prior application Ser. No. 14/469,270 filed on 2014 Aug. 26, a continuation-in-part (CIP) application of prior application Ser. No. 14/586,586 filed on 2014 Dec. 30, and a continuation-in-part (CIP) application of prior application Ser. No. 14/638,989 filed on 2015 Mar. 4. Present application partially seeks the same priority as that of these applications and partially seeks the priority date as 2017 Mar. 30 when present application's provisional application, application No. 62/478,603, was filed. And present application partially seeks the same priority date of the provisional patent application Ser. No. 61/871,840 filed 2013 Aug. 29. The entire contents of each of which are incorporated herein by reference.

### FIELD OF THE ART

Described herein are apparatus and methods for ultra-low quiescent current (lq) load switches with both a reset function and a deep sleep function or capability. These techniques allow ultra-low lq load switches to be used in ultra-portable applications such as smart watches, fitness trackers, and other portable systems where battery life is of the utmost importance. The reset function is important due to a fact that many of these systems are factory sealed and there is no way for a user to conveniently remove the battery should the system come into a non-responsive state. Therefore, if a reset pin is provided, a user may simply press the reset button for a prescribed period of time, say 7 seconds, and the battery will be disconnected by the load switch and then reconnected resulting in a system reset. Additionally, a deep sleep function is also a critical function in storing or shipping of battery operated systems. Using the deep sleep function, a manufacturer can use this function to completely disconnect a battery from a system during storage and shipment. This will prevent the battery from becoming deeply discharged during a storage period. The user can then again, press the button for a prescribed period and the load switch will connect the battery back up to the system, allowing the system to start up without having to be first plugged into a battery charger.

### BACKGROUND

Over the last decade the proliferation of mobile devices has mushroomed. From a creation of a portable digital assistant (PDA) to a further development of smart phones, a need for consumers to have more computing power on a go has risen dramatically. Recent development of small portable systems like smart watches and fitness trackers has extended the development into even smaller form factors requiring the equivalent computing power of a smart phone but with extended battery life. All of these systems need to be managed properly and turned on and off appropriately with an application processor. These portable systems can be plagued with the same problems that can happen to smart phones. The systems can become non-responsive and need to be reset.

Into this environment has emerged an ultra-low lq load switch, a smart version of a Power MOSFET. Load switches of this kind can be used to completely disconnect a battery from systems with extremely low leakage currents extending lives of the small system batteries. A very low R_{DSON} of a load switch in an ON state helps keep its power dissipation low and allows the battery to deliver nearly 100% of its rated voltage to the load. The load switch can be configured to have multiple functions using a single switch input. These functions can be separated in time by pressing an external button for various time lengths.

### SUMMARY OF THE INVENTION

Described herein are apparatus and methods for ultra-low lq slew rate controlled power load switches (PLS) that can be used to perform reset and deep sleep functions in addition to an on and an off functions.

In one aspect, as illustrated in FIGS. 1, 2.1, 2.1, and 3-5, apparatus and methods are provided to control a gate voltage of a PMOS (PS) 101 in a power load switch (PLS) 100 in order to minimize an inrush current flowing from a battery or a voltage source into an output load (OL) 180, that maybe simplified and represented by a capacitor (CL), at an output of the power load switch (PLS) 100. A gate of the PS is connected and controlled by a signal name as load switch control voltage (LSCV) 150, an output of a switching circuit (SC) 107. The SC 107 includes a reset and deep sleep circuit (RDSC) 201 having a reset function and a deep sleep function and a slew rate control circuit (SRCC) 211 connected to an output of the RDSC 201.

In one embodiment of the invention, as illustrated in FIGS. 6.1-6.2, a PLS 100 includes a reset and deep sleep circuit (RDSC) 201 having a reset function and a deep sleep function. The PLS 100 also includes a slew rate control circuit (SRCC) 211 connected to an output of the RDSC 201.

In order to achieve a longer controlled rise time slew rate, an additional implementation of the control circuit is described, which can be used to distinguish from other embodiments.

In a particular embodiment, as illustrated in FIGS. 7.1-7.2, a gate voltage of a PS 101 is provided by a controlled rise time slew rate control circuit (SRCC) 211 that includes a reference current Iref. The on/off state of the controlled rise time slew rate control circuit (SRCC) 211 is controlled by a signal supplied to an enable pin 208 and, when turned on, the Iref current will be divided by a current mirror ratio in order to achieve a necessary slew rate discharge of the PS 101. In this way, the gate discharge current is significantly reduced from a conventional case of just using a resistor to control a current discharge of a switch gate.

In a modification of this described embodiment, as illustrated in FIGS. 8.1-8.2, an oscillator 802 can be used to chop the Iref current and to result in an even longer slew rate controlled discharge of the PS 101. A frequency of the oscillator can be set with a voltage reference to initially to a slowest rise, such as 30 ms, corresponding to a lowest applied voltage. If a shorter rise time is required, the control voltage can be raised causing the frequency of the voltage controlled oscillator to increase thereby reducing the rise time.

Methods that use the circuits described are also set forth.

### BRIEF DESCRIPTION OF THE DRAWINGS

These and other aspects and features will become apparent to those of ordinary skill in the art upon review of the following description of specific embodiments in conjunction with the accompanying figures, wherein:

FIG. 1 illustrates the overall block diagram of the reset load switch with deep sleep capability in present invention.

FIGS. 2.1 and 2.2 illustrate a simplified schematic of a single channel of the reset load switch with deep sleep capability in present invention.

FIG. 3 illustrates a timing diagram of the reset operation in present invention.

FIG. 4 illustrates a timing diagram of the deep sleep function in present invention.

FIG. 5 illustrates one embodiment of the slew rate control part of the load switch in resent invention.

FIGS. 6.1 and 6.2 illustrate a second embodiment of the slew rate control part of the load switch which allows the switch to extend the rise time of the switch turn on time beyond what is capable from the design in FIG. 5 in present invention.

FIGS. 7.1 and 7.2 illustrate a further embodiment of the slew rate control which can be employed to further extend the rise time of the switch beyond what is capable from the designs in FIGS. 5, 6.1, and 6.2 in present invention.

FIGS. 8.1 and 8.2 illustrate a block diagram of the delay circuit that governs the delay time for both the reset function and the deep sleep function in present invention.

### DESCRIPTION OF THE PREFERRED EMBODIMENTS

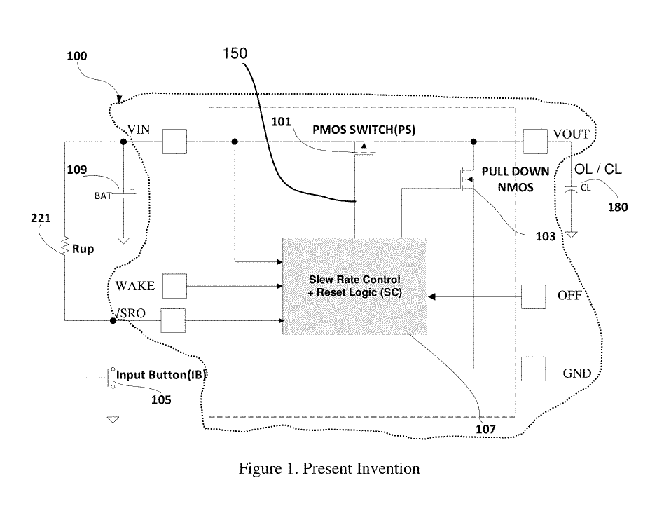

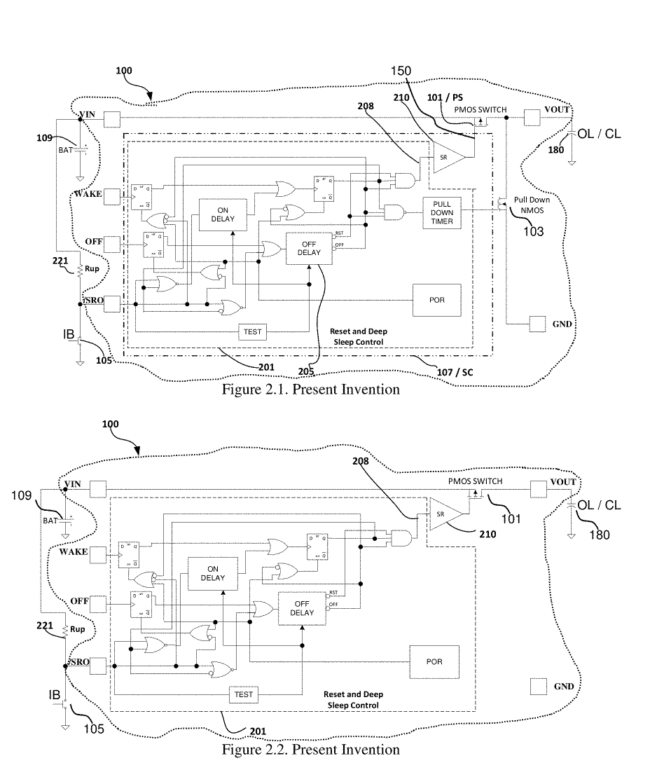

Described herein are methods by which a load switch can be configured to produce dual functions of both a system reset and a deep sleep. The system reset is being issued after a specified time, say N seconds, where N can be chosen to be anything from 1 to 15 preferably, and an initiation of the specified time is caused by a user continuously pressing a reset mechanical switch, i.e., an input button (IB) as illustrated in FIG. 1 and FIGS. 2.1-2.2, for at least the specified time, say a prescribed N seconds, until the system unit is reset. The deep sleep is performed by a use of an OFF input pin as illustrated in FIG. 1 and FIGS. 2.1-2.2. A digital logic value at the OFF input pin is latched after detecting a logic state change and causes at least the specified time, say N second(s), to occur, after that the load switch will turn itself off and remain in an off state thereby causing the system to go into a “deep sleep” mode in order to save power or battery life.

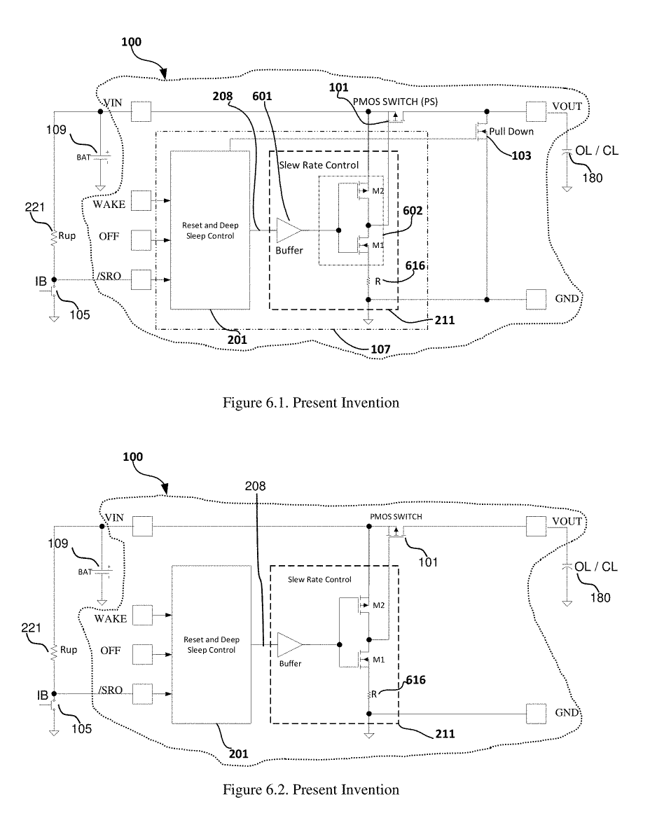

Generally, in preferred embodiments, the load switch includes a PMOS switch (PS) transistor 101 that is connected between an input voltage source such as a battery or independent voltage source and an output load (OL) 180, as illustrated in FIGS. 1-2.2 and FIGS. 6.1-8.2, which could represent a wide variety of electronic circuitry including memory devices, computing devices, or a combination of peripheral devices. Also included is a slew rate control circuit that is connected to the gate of the PMOS switch transistor (PS) 101 as well as a synchronized ON/OFF control circuit. Slew rates of the PS 101 can be controlled in a multiplicity of ways depending upon requirements of the load that the load switch is controlling the voltage into. Some of the methods described herein include a resistive slew rate control method, a current source slew rate control method, and a chopped current source control technique for extremely long turn on times.

It is noted that in adjusting a slew rate, there can be adjustments as to both an amount of time that a voltage rise takes, as well as an extent of the voltage rise. As such, the term “slew rate” is used in the art to refer to both the actual slew rate, as well as to a rise time, and is similarly used herein to mean both; with a reference to the rise time being made when that is specifically being discussed.

Referring to the figures and drawings in detail, FIG. 1 illustrates an overall block diagram of a reset power load switch that has a slew rate control block integrated on the same integrated circuit chip with the power load switch. The power load switch is connected between an input voltage source on a VIN pin to one or more output load device(s) on a VOUT pin. An object of the load switch is to protect the load device(s) from any possible overvoltage condition due to a possible inrush current that can be present when connecting the OL to the voltage source VIN. The slew rate control circuitry can take on many forms to produce a overall result, as described herein. Included within the control block as illustrated in FIG. 1 is a circuitry to perform a reset function which is responsive to an input logic level change on a /SRO input pin and the circuitry necessary to perform the deep sleep function that is responsive to a logic input change on the OFF input pin.

FIGS. 2.1-2.2 illustrate an expanded schematic of the reset and deep sleep control system along with the slew rate control block and the PMOS load switch.

The load switch is controlled by three input functions, /SRO, OFF, and WAKE. Since there are three function controls, there needs to be a priority between the functions in such a way that there can be no conflicts. In a preferred embodiment, the priority is set with /SRO as the top priority overriding all other inputs, then WAKE, and then OFF. The WAKE function is latched and is used to turn the load switch ON from its OFF state. A logical low to high transition on the WAKE input pin will then set the slew rate control system into an ON state without a delay and will cause the slew rate control system to turn on the PMOS switch (PS) 101. There is also a second method that can be used to enable the load switch to be in its ON state, and that is by a use of the /SRO input pin. Using the /SRO input engages an ON DELAY function component, as illustrated in FIG. 2, that requires that the /SRO input pin be held in a logic level zero state for a specified time. This would be customarily done via a mechanical switch, i.e., an input button (IB) 105, with IB's first end connected to the /SRO pin while IB's second end is connected to ground as illustrated in FIG. 1 and FIG. 2. Since the /SRO pin can also be used to reset the load, an IB-pushed-down time for a reset must be different from an IB-pushed-down time for a deep sleep, preferably 2-3 times shorter. For example, say an IB-pushed-down time for a reset is around 6 seconds, then an IB-pushed-down time for a deep sleep might be set to 2 seconds. In that way, the /SRO pin can perform the dual functions. The deep sleep function can also be controlled by the OFF input pin. In the present embodiment, this function shares the OFF delay with the reset function, the difference being that the /SRO function requires a continuous pressing of a mechanical switch for the N seconds of delay time before the reset function can occur, whereas the OFF function is latched in and once latched, the N second delay must run until it times out and the load switch is turned off.

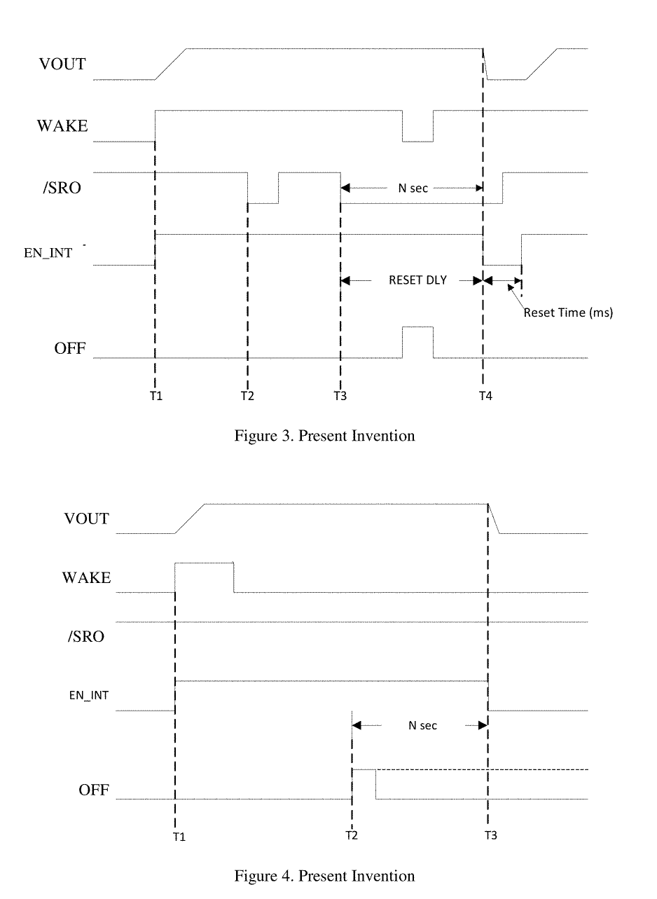

FIG. 3 illustrates a relative timing diagram for the function of the /SRO reset. At time T1, WAKE is provided to turn the load switch ON thereby connecting the VOUT pin to the VIN voltage using a controlled slew rate. At time T2, the /SRO pin is pressed causing the OFF timer to begin counting; however, the /SRO pin is released back to a high level before reaching the N second time out, therefore no action is taken. At time T3, once again the /SRO input is brought to a LOW level and once again the OFF timer begins counting. Since this time the /SRO pin remains in a LOW state for at least the first specified time for reset, say the prescribed N seconds, the reset function is initiated at time T4 causing the VOUT voltage to be brought down to zero volts by disconnecting the VIN pin from the VOUT pin, then after a prescribed further delay, say some several hundred mili-seconds, the load switch is re-enabled and the controlled slew rate allows the VIN voltage to once again be returned to the VOUT load.

In the diagram of FIG. 4, the deep sleep function of the preferred embodiment is shown. In this timing diagram, once again the WAKE function is used to initially connect the VOUT pin to the VIN voltage at time T1. At time T2, the OFF input is exerted HIGH causing the OFF signal to be latched, therefore the OFF signal can be returned to a LOW level or remain HIGH. The OFF delay timer is then initiated for N seconds. At the end of the N second delay, the load switch is turned off at time T3 and the VOUT voltage is brought down to zero volts until either the /SRO input or the WAKE input is used to re-enable the load switch.

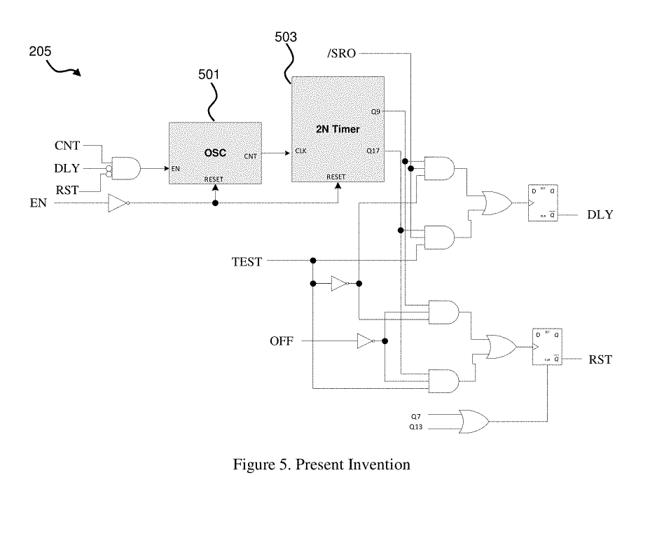

FIG. 5 illustrates a simplified schematic of the OFF delay block in FIG. 2. This block contains an oscillator, a 2^{N} counter, and a control logic. When the block is enabled, there are two possible output paths, one for each function. When the OFF input is exerted HIGH, the logic path to the DLY output is selected because the /SRO input is also HIGH resulting in the deep sleep function. However, when the /SRO input is set to a logic LOW level, OFF is set to LOW due to the priority of /SRO and the path to the RST output is selected resulting in the reset function.

FIGS. 6.1 and 6.2 illustrate how a simple form of slew rate control can be configured. The slew rate control block of this embodiment consists of an input buffer circuit 601 that is connected to the reset control logic. The output of the buffer stage is then connected to an inverter stage that consists of a PMOS pull up transistor labeled M2 and a NMOS pull down transistor labeled M1. In order to control the slew rate of the gate voltage of the PS 101, a resistor R 616 is placed between the source of the NMOS pull down transistor and ground. Thus the current generated to pull down the gate voltage of the PMOS load switch will be:

I_{DSCG}=(V_{GATE}−V_{DS(M1)})/R (1)

The rate at which the gate of the PMOS switch (PS) 101 is discharged can be calculated by using the equation:

Discharge Time=C_{GATE}*VIN/I_{DSCG} (2)

In one embodiment of the invention, as illustrated in FIG. 6.1, a PLS 100 includes a reset and deep sleep circuit (RDSC) 201 having a reset function and a deep sleep function. The PLS 100 also includes a slew rate control circuit (SRCC) 211 connected to an output of the RDSC 201. The RDSC 211 is integrated having an input buffer 601. A state of the SC 107 is controlled by a signal 208 supplied to an input pin of the buffer 601. The output the buffer 601 is connected to an input of an inverter 602 formed and configured by a PMOS transistor M2 and an NMOS transistor M1. A source of the NMOS transistor M1 in the inverter has a resistor R 616 connected to ground. Furthermore it is configured for a slew rate controlled multi-function switch circuit (MFSC) 100 to be turned ON or OFF using the input button (IB) 105. The input button (IB) 105 would have a pull up resistor Rup 221 with its first end connected to a VIN node or terminal of a battery with a voltage, VIN, and its second end (of the pull up resistor) connected to a first end of the IB 105 with a simple function of ON or OFF wherein a second end of the IB 105 is connected to ground. A first end of the IB 105 is connected to the second end of the pull up resistor Rup 221 forming a node called “/SRO” node or pin. If the IB 105 is pressed for a first time period, say 2 seconds, and then released, the MFSC 100 in its OFF state can be turned to its ON state thereby connecting the VIN node to a VOUT node at an output of the MFSC 100 in a controlled manner. Secondly, while the MFSC 100 is in its ON state, MFSC 100 can be placed into a reset mode if the IB 105 is pressed for a second time period, say 7 seconds. During a reset mode, the MFSC 100 is first turned OFF for a third time period, say 0.4 seconds, and then restarted at the end of the third time period, thereby reconnecting the load to the input voltage. A further function can be added to provide a “deep sleep” function by adding an additional input pin. This pin can be labeled “OFF” and its function would be to turn the load switch MFSC 100 into its OFF state after a prescribed delay time, thereby placing the system into a “deep sleep” mode until the IB 105 is pressed for the first time period, say 2 seconds, allowing a wake up function to occur. A further function can be added to provide more flexibilities to a designer. In this embodiment, at and after a battery is newly connected the VIN pin, the MFSC 100 is still kept in its original OFF mode. In order to turn ON the MFSC 100, the IB 105 must be pressed down for a prescribed time, say around 7 seconds. For a faster turn on, an additional input function is added called “WAKE”. If a user requires the MFSC 100 to be in an ON state after first connecting the battery to the VIN pin, the WAKE pin can be utilized by connecting the WAKE pin to the VIN pin using a resistor. This will force the MFSC 100 into an ON state without a time like the first time period.

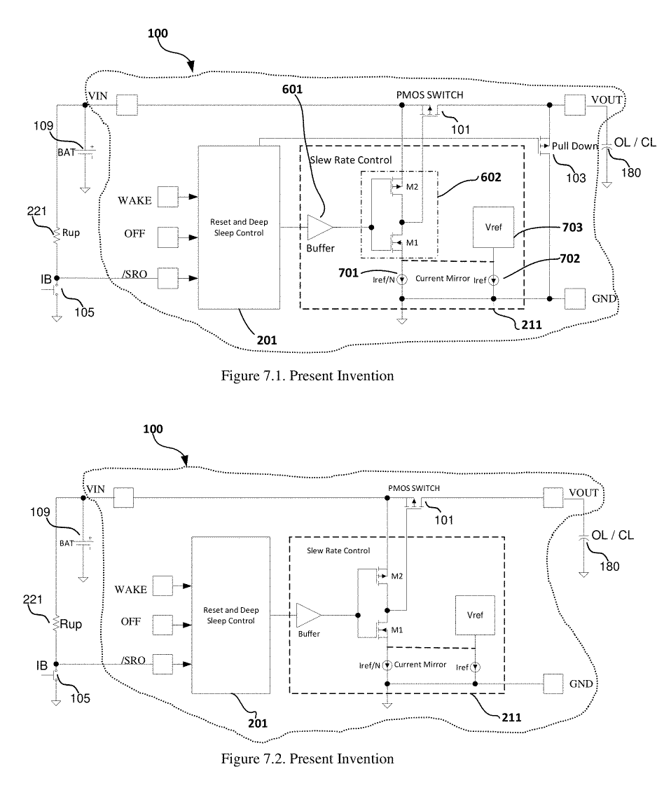

The resistor R 616 in FIGS. 6.1 and 6.2 is replaced by a current mirror 701, in FIGS. 7.1 and 7.2, which obtains a reference current Iref 702 from a stable voltage source Vref 703 provided by a circuit such as a band gap reference circuit. The current mirror 701 is then used to divide the reference current Iref 702 by a dividing ratio N in order to obtain a desired I_{DSCG} current. This technique is used when the turn on time of the PMOS switch (PS) 101 needs to be extended beyond a certain time, say 1-2 ms, which is a practical limit for a resistor based solution.

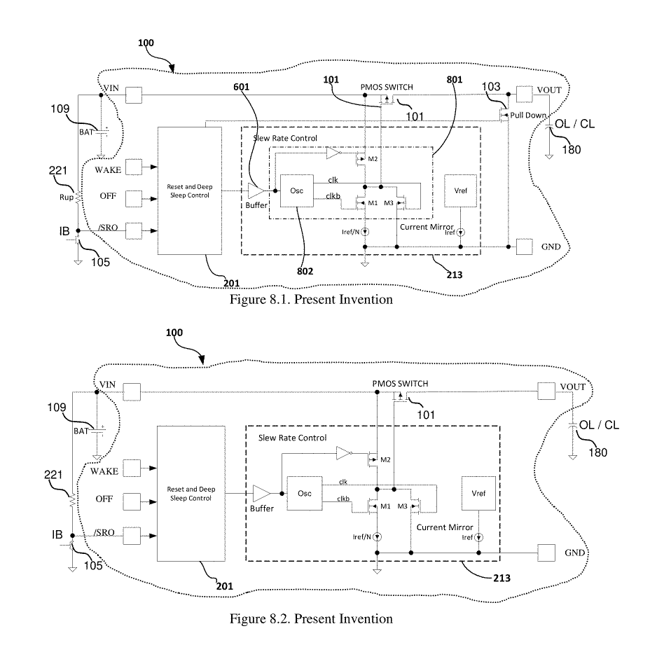

FIGS. 8.1 and 8.2 illustrates a further embodiment of the slew rate control using a chopped reference current where the chopping is delivered by an oscillator 802 with a prescribed duty cycle in order to extend the turn on time of the PMOS switch PS 101 in excess of a desired time, say 30 ms.

Although the embodiments have been particularly described, it should be readily apparent to those of ordinary skill in the art that various changes, modifications and substitutes are intended within the form and details thereof, without departing from their spirit and scope. Accordingly, it will be appreciated that in numerous instances some features will be employed without a corresponding use of other features. Further, those skilled in the art will understand that variations can be made in the number and arrangement of components illustrated in the above figures.

1. A multi-function switching circuit (MFSC) for switchably connecting an external input voltage source (IVS) to an external output load (OL) with a controllable inrush current (CIC) through the OL upon turn-on, the MFSC comprising:
i. a power PMOS transistor (PS) driving the OL with, upon turn-on of the PS, the CIC through the PS;
ii. a switch controller (SC) having a controllable discharge current and an SC output signal, named as load switch control voltage (LSCV), connected to the PS gate for generating the CIC with a controllable rise time and slew rate; and
iii. an input /SRO, an input control signal pin, coupled to an external input button (IB) and a signal input end of the SC for triggering the SC thereby generating the CIC.

2. The MFSC of claim 1 further comprises
i. an input VIN, connectable to the IVS such as an external battery;
ii. an input OFF, connectable to an external signal;
iii. an input WAKE, connectable to an external signal and has a higher priority than the input OFF;
iv. an output VOUT, connectable to the OL;
v. a ground GND;
vi. an ON, i.e., wakeup function;
vii. an OFF, i.e., deep sleep function; and
viii. a reset function.

3. The MFSC of claim 1 wherein the PS comprises
a. a gate G_{P}, electronically connected to the LSCV;
b. a source S_{P}, electronically connected to the input VIN;
c. a drain D_{P}, electronically connected to the output VOUT driving the OL; and
d. a base BP, electronically connected to the source SP.

4. The MFSC of claim 1 wherein the SC comprises
a. a slew rate controller (SRC) comprising
i. a first input IN_{SRC};
ii. a second input; electrically connected to the input VIN
iii. an output OUT_{SRC}, electrically connected to G_{P}; and
iv. a slew rate controller circuit (SRCC); and
b. a reset and deep sleep controller (RDSC) comprising
i. a first input, connected to the input WAKE;
ii. a second input, connected to the input OFF;
iii. a third input, connected to the input /SRO;
iv. a first output, connected to IN_{SRC}; and
v. a reset and deep sleep controller circuit (RDSCC).

5. The MFSC of claim 1 alternatively comprises, if desired for cooperating with the PS for driving the OL, a NMOS pull-down transistor comprising
a. a gate G_{N};
b. a source S_{N}, electrically connected to the ground pin GND;
c. a drain D_{N}, electrically connected to the output pin VOUT; and
d. a base B_{N}, electronically connected to the source S_{N}.

6. The MFSC of claim 1, wherein the input /SRO is switchable between an “open to VIN” state and a “close to a ground” state via the IB and has a higher priority than the input WAKE and the input OFF.

7. The MFSC of claim 4, wherein the RDSCC, for performing the ON, OFF, deep sleep, wakeup, and reset functions, comprises
a. three (3) inputs electrically connected to the WAKE, OFF, and /SRO respectively;
b. a first output for controlling the G_{P};
c. an ON delay circuit comprising
a. an oscillator (OSC) with its input EN connected to input functions of the /SRO input;
b. a 2^{N} timer/counter with its input CLK connected to an output of the oscillator (OSC) with its output connected to an internal digital circuit of the ON delay circuit comprising an output latch that produces a high logic level after the counter has delayed for 2^{N} counts; and
c. a digital circuit comprising latches/flip-flops and logic gates for connecting all terminals and digital components of the circuit and supporting desired functions;
d. an OFF delay circuit comprising
a. an oscillator (OSC) with its input EN connected to input functions of the OFF input or the /SRO;
b. a 2^{N} timer/counter with its input CLK connected to an output of the oscillator (OSC) with its first output and second output connected to an internal digital circuit of the OFF delay circuit comprising an output latch that produces a high logic level after the counter has delayed for 2^{N} counts; and
c. a digital circuit comprising latches/flip-flops and logic gates for connecting all terminals and digital components of the circuit and supporting desired functions;
e. an input latch responsive to a rising input level on the input electrically connected to the WAKE input pin and a delay bypass OR gate that allows the wakeup function to be processed without any prescribed delay
f. an input latch responsive to a rising edge of the input OFF pin signal and using an input path that connects the OFF function to the oscillator (OSC) in the OFF delay circuit thereby controlling the delay function;
g. an input gate responsive to a low level of the input /SRO signal and using an input path that connects the /SRO input function to the oscillator (OSC) in the OFF delay circuit thereby controlling the delay function for the OFF function and the reset function; and
h. a digital circuit comprising latches/flip-flops and logic gates for connecting all terminals and digital components of the RDSCC and supporting desired functions.

8. The MFSC of claim 7 wherein the RDSCC alternatively comprises, if desired, a second output electrically connected to the G_{N}, for driving a desirable but optional NMOS pull-down transistor cooperating with the PS for driving the OL.

9. The MFSC of claim 2, wherein the ON or wakeup function comprises following feature(s) that
a. the output VOUT rises without any prescribed delay after the input WAKE rises if previously the VOUT is low and the input /SRO is high, thus turning on the external load without any prescribed delay, supported by the input latch, in the RDSCC, which is responsive to a rising input level on the input electrically connected to the WAKE input pin and a delay bypass OR gate, in the RDSCC, that allows the wakeup function to be processed without any prescribed delay; or
b. the output VOUT rises with a controlled slew rate after the input /SRO falls and stays low for a prescribed time, on delay, preferably around 2 seconds, supported by the ON delay circuit in the RDSCC and the SRC, if previously the output VOUT is low and the input /SRO is high, thus turning on the external load.

10. The MFSC of claim 2, wherein the OFF or deep sleep function comprises feature(s) that
a. after a rising edge of the input OFF for a prescribed delay, off delay, preferably around 6 or 7 seconds, supported by the OFF delay circuit in the RDSCC and the SRC, the output VOUT falls with a controlled slew rate thus turning off the external load or letting the external load enter a deep sleep mode; and
b. after the input /SRO stays low for a prescribed delay preferably 2 seconds, the G_{P} falls and so the output VOUT falls.

11. The MFSC of claim 2, wherein the reset function comprises a feature that after the /SRO stays low for a prescribed time, a reset delay, preferably around 7 seconds, counted by the 2^{N} timer/counter in the OFF delay circuit for 2^{N} counts, then the output VOUT falls and stays at low for a prescribed time, reset time, preferably around 0.4 seconds, counted by the 2^{N} timer/counter in the ON delay circuit for 2^{N-4} counts, and then rises.

12. The MFSC of claim 4, wherein the SRCC comprises
i. a buffer comprising an input and an output, wherein the input is electrically connected to the first output of the RDSCC; and
ii. an inverter comprising an NMOS transistor M1, a PMOS transistor M2, an input, an output, a power supply terminal, and a ground terminal, wherein
a. the output the inverter is electrically connected to the G_{P};
b. the power supply terminal of the inverter is electrically connected to the VIN;
c. the ground terminal of the inverter is electrically connected to the GND via a resister controlling a discharge current for controlling a slew rate of the PS; and
d. the input of the inverter is electrically connected to the output of the buffer.

13. The MFSC of claim 4, wherein the SRCC, alternatively, comprises
i. a buffer comprising an input and an output, wherein the input is electrically connected to the first output of the RDSCC;
ii. an inverter comprising an NMOS transistor M1, a PMOS transistor M2, an input, an output, a power supply terminal, and a ground terminal, wherein
a. the output the inverter is electrically connected to the G_{P};
b. the power supply terminal of the inverter is electrically connected to the VIN; and
c. an input of the inverter is electrically connected to the output of the buffer;
iii. a voltage reference source Vref, preferably a bandgap reference;
iv. a current reference Iref, derived from the Vref, in a direction from the Vref to a ground; and
v. a current mirror circuit allowing the Iref to be divided by an integer N thus generating a mirrored current source Iref/N, in a direction from a source of the M1 to a ground, in order to achieve a controlled slew rate rise time in excess of a desired time range, preferably around 1 ms to 2 ms.

14. The MFSC of claim 4, wherein the SRCC, alternatively, comprises
i. a buffer comprising an input and an output, wherein the input is electrically connected to the first output of the RDSCC;
ii. an inverter comprising an input and an output, wherein the input is electrically connected to the output of the buffer;
iii. an oscillator comprising an input, an first output CLK, and a second output CLKB, wherein the input is electrically connected to the output of the buffer, providing a clock signal to a current reference chopping circuit in order to control a slew rate voltage on the G_{P} of the PS; in which the duty cycle of the clock determines the ON time of the current reference chopping circuit.
iv. an NMOS transistor M1, wherein
a. a gate of the M1 is electrically connected to the CLKB; and
b. a drain of the M1 is electrically connected to the G_{P};
v. a PMOS transistor M2, wherein
a. a gate of the M2 is electrically connected the output of the inverter;
b. a source of the M2 is electrically connected to the G_{P}; and
c. a drain of the M2 is electrically connected to the VIN;
vi. an NMOS transistor M3, wherein
a. a gate of the M3 is electrically connected to the CLK;
b. a source of the M3 is electrically connected to a ground; and
c. a drain of the M3 is electrically connected to the G_{P};
vii. a voltage reference source Vref, preferably a bandgap reference;
viii. a current reference Iref, derived from the Vref, in a direction from the Vref to a ground; and
ix. a current mirror circuit allowing the Iref to be divided by an integer N thus generating a mirrored current source Iref/N, in a direction from a source of the M1 to a ground, in order to achieve a controlled slew rate rise time in excess of a desired time range, preferably around 30 ms.

15. A method for switchably connecting an external input voltage source (IVS) to an external output load (OL) with a controllable inrush current (CIC) through the OL upon turn-on, the method comprises providing a multi-function switching circuit (MFSC) for switchably connecting the IVS to the OL wherein providing the MFSC comprising providing:
i. a power PMOS transistor (PS) driving the OL with, upon turn-on of the PS, the CIC through the PS;
ii. a switch controller (SC) having a controllable discharge current and an SC output signal, named as load switch control voltage (LSCV), connected to the PS gate for generating the CIC with a controllable rise time and slew rate; and
iii. an input /SRO, an input control signal pin, coupled to an external input button (IB) and a signal input end of the SC for triggering the SC thereby generating the CIC.

16. The method of providing the MFSC of claim 15 further comprises providing
i. an input VIN, connectable to the IVS such as an external battery;
ii. an input OFF, connectable to an external signal;
iii. an input WAKE, connectable to an external signal and has a higher priority than the input OFF;
iv. an output VOUT, connectable to the OL;
v. a ground GND;
vi. an ON, i.e., wakeup function;
vii. an OFF, i.e., deep sleep function; and
viii. a reset function.

17. The method of providing the MFSC of claim 15 wherein providing the PS comprises providing
a. a gate G_{P}, electronically connected to the LSCV;
b. a source S_{P}, electronically connected to the input VIN;
c. a drain D_{P}, electronically connected to the output VOUT driving the OL; and
d. a base BP, electronically connected to the source SP.

18. The method of providing the MFSC of claim 15 wherein providing the SC comprises providing
a. a slew rate controller (SRC) comprising
i. a first input IN_{SRC};
ii. a second input; electrically connected to the input VIN
iii. an output OUT_{SRC}, electrically connected to G_{P}; and
iv. a slew rate controller circuit (SRCC); and
b. a reset and deep sleep controller (RDSC) comprising
i. a first input, connected to the input WAKE;
ii. a second input, connected to the input OFF;
iii. a third input, connected to the input /SRO;
iv. a first output, connected to IN_{SRC}; and
v. a reset and deep sleep controller circuit (RDSCC).

19. The method of providing the MFSC of claim 15 alternatively comprises, if desired for cooperating with the PS for driving the OL, providing a NMOS pull-down transistor comprising providing
a. a gate G_{N};
b. a source S_{N}, electrically connected to the ground pin GND;
c. a drain D_{N}, electrically connected to the output pin VOUT; and
d. a base B_{N}, electronically connected to the source S_{N}.

20. The method of providing the MFSC of claim 15, wherein providing the input /SRO comprises providing a switching ability between an “open to VIN” state and a “close to a ground” state via the IB and having a higher priority than the input WAKE and the input OFF.

21. The method of providing the MFSC of claim 18 wherein providing the RDSCC, for performing the ON, OFF, deep sleep, wakeup, and reset functions, comprises providing
a. three (3) inputs electrically connected to the WAKE, OFF, and /SRO respectively;
b. a first output for controlling the G_{P};
c. an ON delay circuit comprising
a. an oscillator (OSC) with its input EN connected to input functions of the /SRO input;
b. a 2^{N} timer/counter with its input CLK connected to an output of the oscillator (OSC) with its output connected to an internal digital circuit of the ON delay circuit comprising an output latch that produces a high logic level after the counter has delayed for 2^{N} counts; and
c. a digital circuit comprising latches/flip-flops and logic gates for connecting all terminals and digital components of the circuit and supporting desired functions;
d. an OFF delay circuit comprising
a. an oscillator (OSC) with its input EN connected to input functions of the OFF input or the /SRO;
b. a 2^{N} timer/counter with its input CLK connected to an output of the oscillator (OSC) with its first output and second output connected to an internal digital circuit of the OFF delay circuit comprising an output latch that produces a high logic level after the counter has delayed for 2^{N} counts; and
c. a digital circuit comprising latches/flip-flops and logic gates for connecting all terminals and digital components of the circuit and supporting desired functions;
e. an input latch responsive to a rising input level on the input electrically connected to the WAKE input pin and a delay bypass OR gate that allows the wakeup function to be processed without any prescribed delay
f. an input latch responsive to a rising edge of the input OFF pin signal and using an input path that connects the OFF function to the oscillator (OSC) in the OFF delay circuit thereby controlling the delay function;
g. an input gate responsive to a low level of the input /SRO signal and using an input path that connects the /SRO input function to the oscillator (OSC) in the OFF delay circuit thereby controlling the delay function for the OFF function and the reset function; and
h. a digital circuit comprising latches/flip-flops and logic gates for connecting all terminals and digital components of the RDSCC and supporting desired functions.

22. The method of providing the MFSC of claim 21 wherein providing the RDSCC alternatively comprises, if desired, providing a second output electrically connected to the G_{N}, for driving a desirable but optional NMOS pull-down transistor cooperating with the PS for driving the OL.

23. The method of providing the MFSC of claim 16, wherein providing the ON or wakeup function comprises providing following feature(s) that
a. the output VOUT rises without any prescribed delay after the input WAKE rises if previously the VOUT is low and the input /SRO is high, thus turning on the external load without any prescribed delay, supported by the input latch, in the RDSCC, which is responsive to a rising input level on the input electrically connected to the WAKE input pin and a delay bypass OR gate, in the RDSCC, that allows the wakeup function to be processed without any prescribed delay; or
b. the output VOUT rises with a controlled slew rate after the input /SRO falls and stays low for a prescribed time, on delay, preferably around 2 seconds, supported by the ON delay circuit in the RDSCC and the SRC, if previously the output VOUT is low and the input /SRO is high, thus turning on the external load.

24. The method of providing the MFSC of claim 16, wherein providing the OFF or deep sleep function comprises providing feature(s) that
a. after a rising edge of the input OFF for a prescribed delay, off delay, preferably around 6 or 7 seconds, supported by the OFF delay circuit in the RDSCC and the SRC, the output VOUT falls with a controlled slew rate thus turning off the external load or letting the external load enter a deep sleep mode; and
b. after the input /SRO stays low for a prescribed delay preferably 2 seconds, the G_{P} falls and so the output VOUT falls.

25. The method of providing the MFSC of claim 16, wherein providing the reset function comprises providing a feature that after the /SRO stays low for a prescribed time, a reset delay, preferably around 7 seconds, counted by the 2^{N} timer/counter in the OFF delay circuit for 2^{N} counts, then the output VOUT falls and stays at low for a prescribed time, reset time, preferably around 0.4 seconds, counted by the 2^{N} timer/counter in the ON delay circuit for 2^{N-4} counts, and then rises.

26. The method of providing the MFSC of claim 18, wherein providing the SRCC comprises providing
i. a buffer comprising an input and an output, wherein the input is electrically connected to the first output of the RDSCC; and
ii. an inverter comprising an NMOS transistor M1, a PMOS transistor M2, an input, an output, a power supply terminal, and a ground terminal, wherein
a. the output the inverter is electrically connected to the G_{P};
b. the power supply terminal of the inverter is electrically connected to the VIN;
c. the ground terminal of the inverter is electrically connected to the GND via a resister controlling a discharge current for controlling a slew rate of the PS; and
d. the input of the inverter is electrically connected to the output of the buffer.

27. The method of providing the MFSC of claim 18, alternatively, comprises providing
i. a buffer comprising an input and an output, wherein the input is electrically connected to the first output of the RDSCC;
ii. an inverter comprising an NMOS transistor M1, a PMOS transistor M2, an input, an output, a power supply terminal, and a ground terminal, wherein
a. the output the inverter is electrically connected to the G_{P};
b. the power supply terminal of the inverter is electrically connected to the VIN; and
c. an input of the inverter is electrically connected to the output of the buffer;
iii. a voltage reference source Vref, preferably a bandgap reference;
iv. a current reference Iref, derived from the Vref, in a direction from the Vref to a ground; and
v. a current mirror circuit allowing the Iref to be divided by an integer N thus generating a mirrored current source Iref/N, in a direction from a source of the M1 to a ground, in order to achieve a controlled slew rate rise time in excess of a desired time range, preferably around 1 ms to 2 ms.

28. The method of providing the MFSC of claim 18, wherein providing the SRCC, alternatively, comprises providing
i. a buffer comprising an input and an output, wherein the input is electrically connected to the first output of the RDSCC;
ii. an inverter comprising an input and an output, wherein the input is electrically connected to the output of the buffer;
iii. an oscillator comprising an input, an first output CLK, and a second output CLKB, wherein the input is electrically connected to the output of the buffer, providing a clock signal to a current reference chopping circuit in order to control a slew rate voltage on the G_{P} of the PS; in which the duty cycle of the clock determines the ON time of the current reference chopping circuit.
iv. an NMOS transistor M1, wherein
a. a gate of the M1 is electrically connected to the CLKB; and
b. a drain of the M1 is electrically connected to the G_{P};
v. a PMOS transistor M2, wherein
a. a gate of the M2 is electrically connected the output of the inverter;
b. a source of the M2 is electrically connected to the G_{P}; and
c. a drain of the M2 is electrically connected to the VIN;
vi. an NMOS transistor M3, wherein
a. a gate of the M3 is electrically connected to the CLK;
b. a source of the M3 is electrically connected to a ground; and
c. a drain of the M3 is electrically connected to the G_{P};
vii. a voltage reference source Vref, preferably a bandgap reference;
viii. a current reference Iref, derived from the Vref, in a direction from the Vref to a ground; and
ix. a current mirror circuit allowing the Iref to be divided by an integer N thus generating a mirrored current source Iref/N, in a direction from a source of the M1 to a ground, in order to achieve a controlled slew rate rise time in excess of a desired time range, preferably around 30 ms.
